(19) United States
(12) Patent Application Publication
(10) Pub. No.: US 2026/0255995 A1
(43) Pub. Date: Aug. 27, 2026

(54) SUBSTRATE AND MANUFACTURING METHOD THEREOF

(71) Applicant: Dyi-Chung HU, Hsinchu County (TW)

(72) Inventor: Dyi-Chung HU, Hsinchu County (TW)

(21) Appl. No.: 19/063,119

(22) Filed: Feb. 25, 2025

(51) Int. Cl. H01L 23/498

(52) U.S. Cl. CPC H10W 70/635; H10W 70/66; H10W 90/701

(57) ABSTRACT

A substrate includes a first circuit unit, a second circuit unit, and a conductive connector structure. The first circuit unit includes a first base layer and a first via structure penetrated through the first base layer, wherein the first via structure has a plurality of first through vias, one of the plurality of first through vias has an optical member and an annular insulator located beside the optical member. The second circuit unit includes a second base layer and a second via structure penetrated through the second base layer. The second circuit unit is bonded and electrically connected to the first circuit unit by the conductive connector structure. A manufacturing method of a substrate is also provided.

### BACKGROUND

### Technical Field

The disclosure is related to a substrate and manufacturing method thereof.

### Description of Related Art

In order to meet the needs of the product for better application, the design of substrate has become a challenge to researchers in the field. For example, how to improve the reliability is important.

### SUMMARY

A substrate includes a first circuit unit, a second circuit unit, and a conductive connector structure. The first circuit unit includes a first base layer and a first via structure penetrated through the first base layer, wherein the first base layer includes ceramic. The second circuit unit includes a second base layer and a second via structure penetrated through the second base layer, wherein the second base layer comprises glass. The second circuit unit is bonded and electrically connected to the first circuit unit by the conductive connector structure.

A manufacturing method of a substrate includes providing a first circuit unit including a first base layer and a first via structure penetrated through the first base layer, wherein the first base layer includes ceramic; forming a conductive connector structure on the first circuit unit; providing a second circuit unit including a second base layer and a second via structure penetrated through the second base layer, wherein the second base layer includes glass; and bonding and electrically connecting the second circuit unit to the first circuit unit by the conductive connector structure.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 to FIG. 2 are partial schematic cross-sectional views illustrating a manufacturing method of a substrate according to some embodiments of the disclosure.

FIG. 3, FIG. 4, FIG. 5, FIG. 6A and FIG. 7A are partial schematic cross-sectional views illustrating substrates according to some embodiments of the disclosure.

FIG. 6B, FIG. 6C, FIG. 6D are partial schematic top views corresponding to FIG. 6A.

FIG. 7B, FIG. 7C, FIG. 7D are partial schematic top views corresponding to FIG. 7A.

### DESCRIPTION OF THE EMBODIMENTS

Exemplary embodiments of the disclosure are described below comprehensively with reference to the figures, but the disclosure may also be implemented in different ways and should not be construed as limited to the embodiments described herein. In the drawings, for the sake of clarity, the size and thickness of various regions, parts, and layers may not be drawn to actual scale. In order to facilitate understanding, the same elements in the following description are described with the same symbols.

The disclosure is more comprehensively described with reference to the figures of this embodiment. However, the disclosure may also be implemented in various different forms, and is not limited to the embodiments in the present specification. Thicknesses, dimensions, and sizes of layers or regions in the drawings are exaggerated for clarity. The same reference numbers are used in the drawings and the description to indicate the same or like parts, which are not repeated in the following embodiments.

Directional terms (for example, upper, lower, right, left, front, back, top, and bottom) used herein only refer to the graphical use, and are not intended to imply absolute orientation.

It should be understood that, although the terms “first”, “second”, “third”, or the like may be used herein to describe various elements, components, regions, layers, and/or portions, these elements, components, regions, and/or portions should not be limited by these terms. These terms are only used to distinguish one element, component, region, layer, or portion from another element, component, region, layer, or portion.

Unless otherwise defined, all terms (including technical and scientific terms) used herein have the same meaning as that commonly understood by one of ordinary skill in the art to which this disclosure belongs.

Unless otherwise stated, the term “range from” used in the specification to define a value range is intended to cover a range equal to and between the stated endpoint values. For example, a size range ranges from a first value to a second value means that the size range may cover the first value, the second value, and any value between the first value and the second value.

In the substrate, the reliability may be influenced by many aspects. For example, when a structural strength is worse, the reliability may be reduced. One way to improve aforementioned problem is to increase a thickness of entirely structure, however, this way may let substrate cannot be lighter, thinner, and smaller. In the present disclosure, the use of a circuit unit including ceramic may make the substrate have a greater structural strength with a smaller thickness, and the use of the circuit unit including glass may be more suitable for manufacturing a fine circuitry. By doing so, the reliability of the substrate may be effectively improved, while the substrate also has the advantage of high integration.

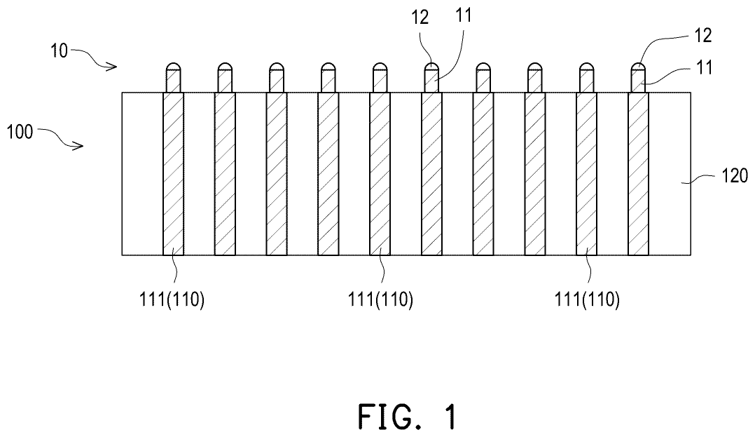

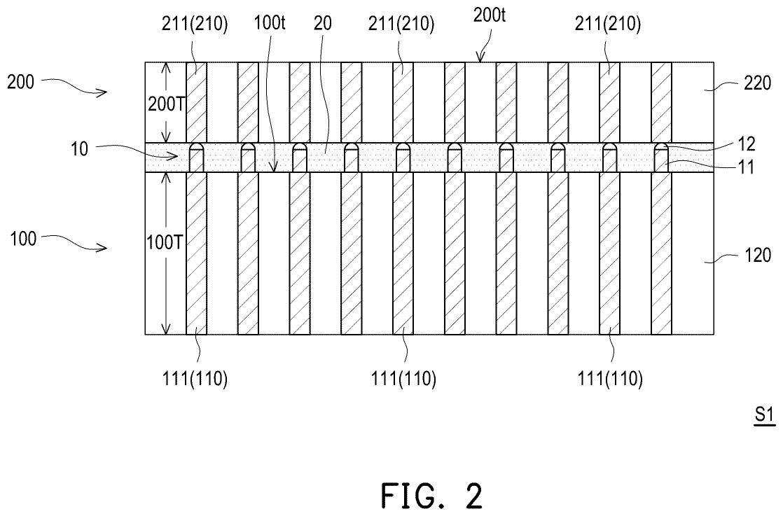

FIG. 1 to FIG. 2 are partial schematic cross-sectional views illustrating a manufacturing method of a substrate according to some embodiments of the disclosure.

Referring to FIG. 1, a circuit unit 100 is provided. For example, a via structure 110 is formed in and penetrated through a base layer 120. In the embodiment, for improving the structural strength, the higher Young's modulus materials may be used, thereby the base layer 120 comprises ceramic, therefore, the via structure 110 may be referred as TCV structure. In some embodiments, the via structure 110 includes a plurality of through vias 111 and may be manufactured as follow. First, portions of the base layer 120 are removed to form a plurality of openings (not shown), wherein the removal process is by laser modification followed by a chemical etching process with suitable etchant, but the disclosure is not limited thereto, other suitable removal process may be used. And then, the conductive material (such as copper or the like) may be plating in the openings to form the through vias 111. Here, heights of the through vias 111 may be the same, but the disclosure is not limited thereto.

In FIG. 1, a conductive connector structure 10 is formed on the circuit unit 100, wherein the conductive connector structure 10 is electrically connected to the circuit unit 100. In the embodiment, the conductive connector structure 10 has a plurality of conductive pillars 11 and a plurality of conductive caps 12 located on the conductive pillars 11 respectively. In some embodiments, the material of the conductive pillars 11 may include copper, and the material of the conductive caps 12 may include solder. Further, the conductive pillars 11 and the conductive caps 12 may be formed by any suitable process. Here, heights of the conductive pillars 11 may be the same, but the disclosure is not limited thereto.

Referring to FIG. 2, a circuit unit 200 is provided. For example, a via structure 210 is formed in and penetrated through a base layer 220. In the embodiment, for improving quality of the fine circuitry with fine pitch (may be 0.5 micrometers), the base layer 220 comprises glass, therefore, the via structure 210 may be referred as TGV structure. For example, a roughness of a top surface 200t away from the conductive connector structure 10 of the circuit unit 200 may be about 10 nano angstrom), therefore, a flat surface may be provided to allow the fine circuitry formed thereon to have high quality, but the disclosure is not limited thereto, other suitable value may be design. In some embodiments, a roughness of a top surface 100t beside the conductive connector structure 10 of the circuit unit 100 is rougher than the roughness of the top surface 200t of the circuit unit 200. For example, the roughness of the top surface 100t may be about 1 micrometers), but the disclosure is not limited thereto, other suitable value may be design.

In some embodiments, the via structure 210 includes a plurality of through vias 211 and may be manufactured as follow. First, portions of the base layer 220 are removed to form a plurality of openings (not shown), wherein the removal process is by laser modification followed by a chemical etching process with suitable etchant, but the disclosure is not limited thereto, other suitable removal process may be used. And then, the conductive material (such as copper or the like) may be plating in the openings to form the through vias 211.

In FIG. 2, the circuit unit 200 is bonded and electrically connected to the circuit unit 100 by the conductive connector structure 10. For example, the conductive pillars 11 of the conductive connector structure 10 may be direct in contact with the through vias 111, and the conductive caps 12 of the conductive connector structure 10 may be direct in contact with the through vias 211, such that a vertical electrical path is formed. Here, number of the through vias 111, number of the conductive pillars 11, number of the conductive caps 12, and number of the through vias 211 are the same, a one-to-one correspondence connection manner may be used in the structure, but the disclosure is not limited thereto.

In some embodiments, a thickness 100T of the circuit unit 100 is greater than a thickness 200T of the circuit unit 200 to further enforce structural strength of the entirely structure and aspect ratio of the circuit unit 200 may be decreased at same time to reduce the difficulty of production. For example, the thickness 100T of the circuit unit 100 ranges from 300 micrometers to 1000 micrometers, and the thickness 200T of the circuit unit 200 ranges from 100 micrometers to 500 micrometers, but the disclosure is not limited thereto.

Further, after bonding the circuit unit 200 to the circuit unit 100, an underfill 20 is formed in gaps between the circuit unit 100 and the circuit unit 200, therefore, the conductive connector structure 10 may be protected. For example, the glue or other suitable materials may surround, cover, and wrap the conductive connector structure 10. The manufacturing of a substrate S1 is roughly completed via the above steps.

In the present disclosure, the use of a circuit unit 100 including ceramic may make the substrate have a greater structural strength with a smaller thickness, and the use of the circuit unit 20 including glass may be more suitable for manufacturing a fine circuitry. By doing so, the reliability of the substrate S1 may be effectively improved, while the substrate S1 also has the advantage of high integration.

It is to be noted that the following embodiments use the reference numerals and a part of the contents of the above embodiment, and the same or similar reference numerals are used to denote the same or similar elements, and the description of the same technical content is omitted. For the description of the omitted part, reference may be made to the above embodiments, and details are not described in the following embodiments.

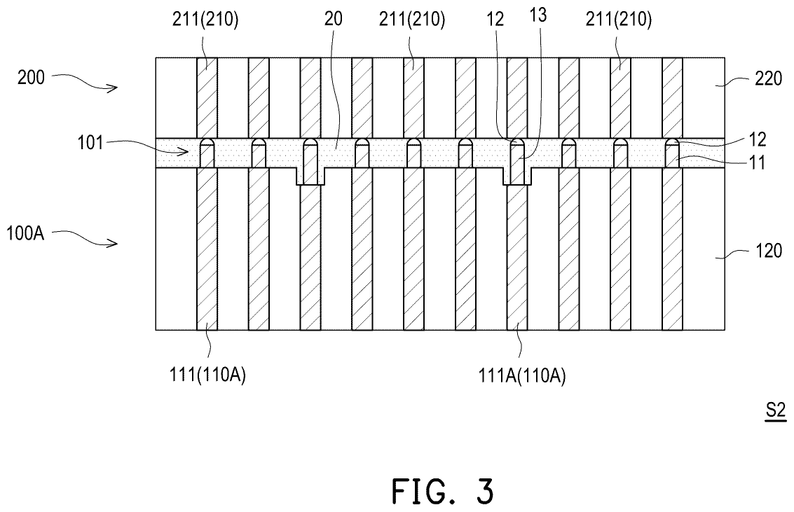

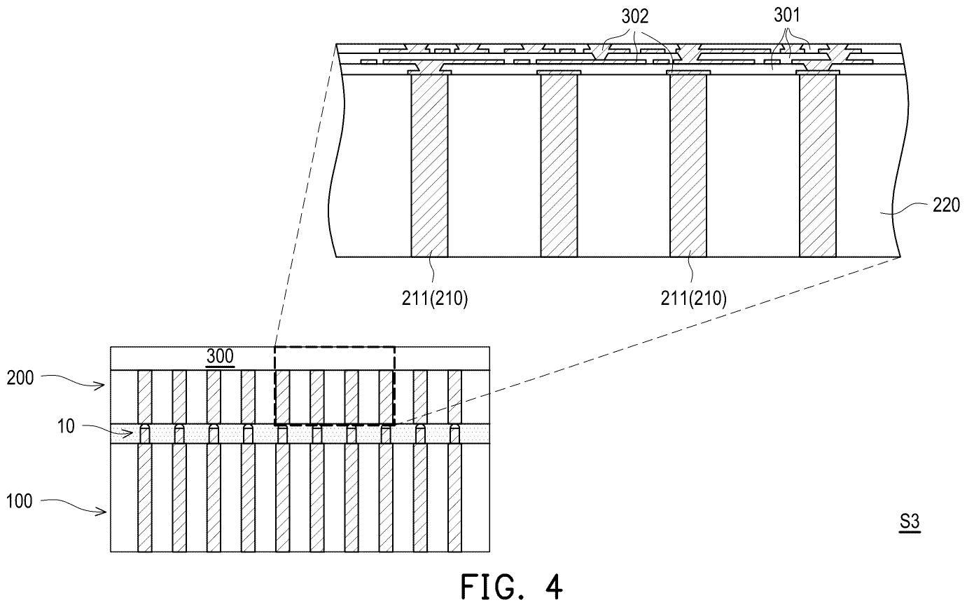

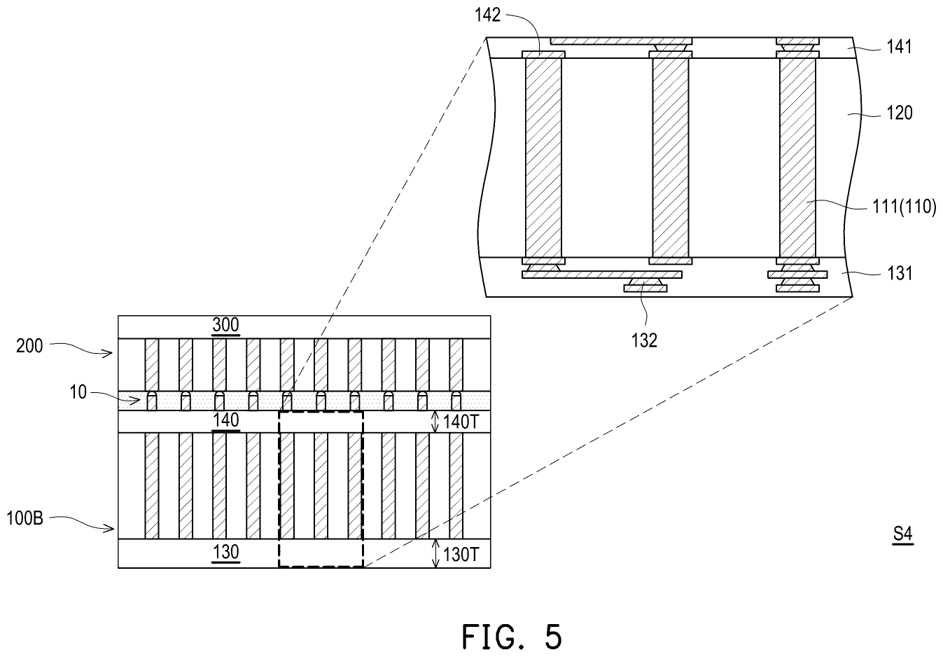

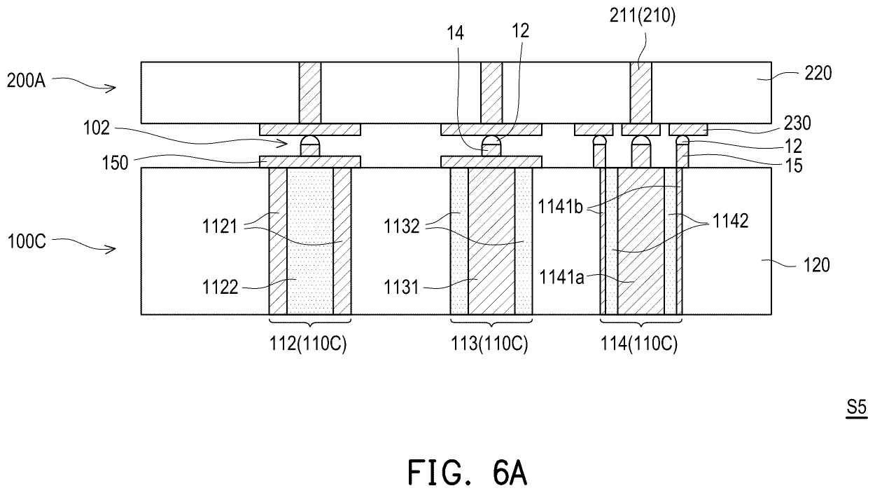

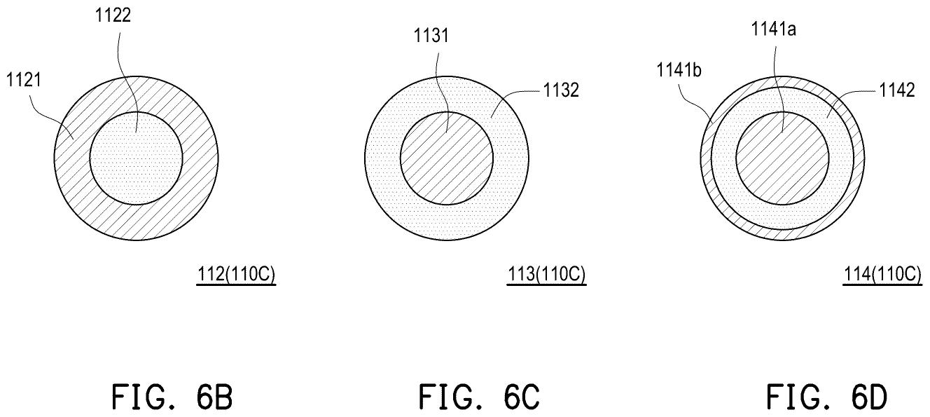

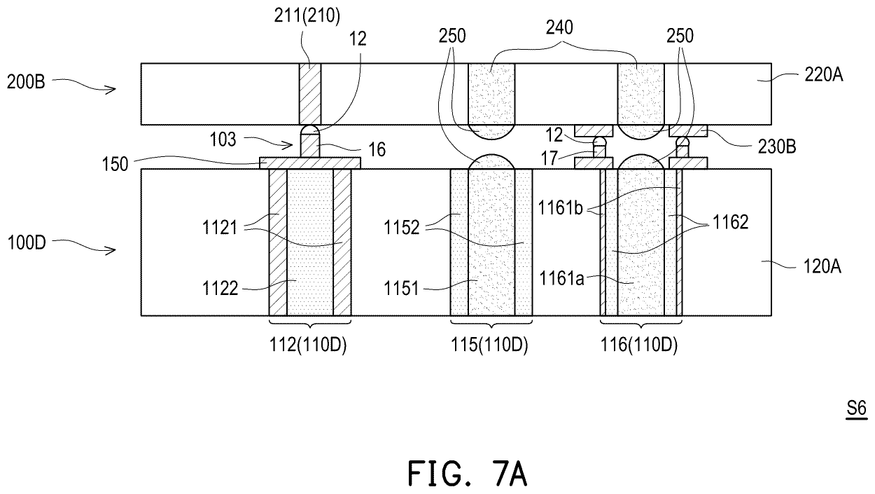

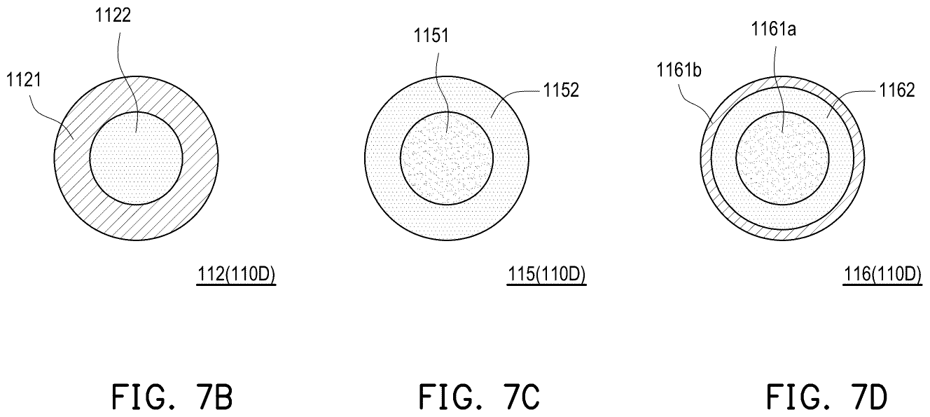

FIG. 3, FIG. 4, FIG. 5, FIG. 6A and FIG. 7A are partial schematic cross-sectional views illustrating substrates according to some embodiments of the disclosure. FIG. 6B, FIG. 6C, FIG. 6D are partial schematic top views corresponding to FIG. 6A. FIG. 7B, FIG. 7C, FIG. 7D are partial schematic top views corresponding to FIG. 7A.

Referring to FIG. 3, similar to the substrate S1 of FIG. 2, the difference is a circuit unit 100A of a substrate S2 of this embodiment further comprises a recess due to rough surface, and the underfill 20 is filled up the recess, while a conductive connector structure 101 of the substrate S2 has height adjustment function. For example, the through vias of the circuit unit 100A have a through via 111 and a through via 111A shorter than the through via 111, such that a top surface of the through via 111 and a top surface of the through via 111A are not located at a same level. Moreover, the conductive pillars of the conductive connector structure 101 have a conductive pillar 11 and a conductive pillar 13 taller than the conductive pillar 11, therefore, the conductive pillar 13 (taller one) is formed on the through via 111A (shorter one), thereby a top surface of the conductive pillar 11 and a top surface of the conductive pillar 13 are located at a same level. By doing so, the conductive pillars in different height may compensate for the through vias in different height caused by the rough surface of circuit unit 100A.

Referring to FIG. 4, similar to the substrate S1 of FIG. 2, the difference is a substrate S3 of this embodiment further includes forming a redistribution structure 300 on the circuit unit 200. For example, a plurality of dielectric layers 301 of the redistribution structure 300 are formed by laminating dielectric material (such as PSPI (Photosensitive Polyimide), ABF, PP, or the like) over the circuit unit 200, and a plurality of conductive layers 302 of the redistribution structure 300 are formed in the dielectric layers 301. The dielectric layers 301 in the build-up structures insulate the conductive layers 302. Herein the first circuit structure 300 may be formed by suitable processes (such as photolithography, etch, or the like), the disclosure is not limited thereto. In some embodiments, the conductive elements (e.g., conductive patterns, conductive vias, conductive lines, or conductive pads) of the conductive layers 302 are finer elements to composed the fine circuitry, but the disclosure is not limited thereto. On the other hand, in unillustrated embodiment, a carrier may be used in forming process of the redistribution structure 300, but the disclosure is not limited thereto.

Referring to FIG. 5, similar to the substrate S1 of FIG. 2, the difference is a circuit unit 100B of a substrate S4 of this embodiment further includes a redistribution structure 130 and a redistribution structure 140 disposed on the opposite surfaces of the base layer 120 and the via structure 110 respectively. For example, a plurality of dielectric layers 131 of the redistribution structure 130 and a plurality of dielectric layers 141 of the redistribution structure 140 are formed by laminating dielectric material (such as PSPI (Photosensitive Polyimide), ABF, PP, or the like), and a plurality of conductive layers 132 of the redistribution structure 130 and a plurality of conductive layers 142 of the redistribution structure 140 are respectively formed in the dielectric layers 131 and the dielectric layers 141. The dielectric layers (e.g., 131, 141) in the build-up structures insulate the conductive layer (e.g., 132, 142), from conductive traces underneath the dielectric layer (e.g., 131, 141). Herein the redistribution structure 130 and the redistribution structure 140 may be formed by suitable processes (such as photolithography, etch, or the like), the disclosure is not limited thereto.

In some embodiments, a thickness 130T of the redistribution structure 130 away from the conductive connector structure 10 is greater than a thickness 140T of the redistribution structure 140 near the conductive connector structure 10, by doing so, the redistribution structure 130 may be used to provide a pitch coarse than the pitch of the redistribution structure 140, but the disclosure is not limited thereto.

Referring to FIG. 6A to FIG. 6D, in the embodiment, a substrate S5 includes a circuit unit 100C, a circuit unit 200A, and a conductive connector structure 102. The circuit unit 100C includes a base layer 120 and a via structure 110C penetrated through the base layer 120, wherein the base layer 120 includes ceramic. The circuit unit 200A includes a base layer 220 and a via structure 210 penetrated through the base layer 220, wherein the second base layer 220 comprises glass. The circuit unit 200A is bonded and electrically connected to the circuit unit 100C by the conductive connector structure 102. In unillustrated embodiment, the circuit unit 100C and conductive connector structure 102 may be arranged similar to the substrate S2 in FIG. 3.

In the embodiment, the circuit unit 100C has a connection line 150, and the via structure 110C including through vias 112, 113, 114. To be specific, the through via 112 has an annular conductive member 1121 and an insulator 1122 located in the annular conductive member 1121, and the annular conductive member 1121 is electrically connected to the connection line 150. Further, the through via 113 has a conductive member 1131 and an annular insulator 1132 surrounding the conductive member 1131. Moreover, the through via 114 has a central member 1141a including conductive material, an annular edge member 1141b, and an annular insulator 1142 located between the central member 1141a and the annular edge member 1141b, therefore, there are two electrical paths in the through via 114. Here, the annular edge member 1141b may have ground function. In addition, the insulator 1122, 1132, 1142 may reduce stress between in the circuit unit 100C, wherein the insulator 1122, 1132, 1142 may use any suitable insulating material. Here, each size of the through vias 112, 113, 114 may be greater than a size of the through via 211.

In the embodiment, the circuit unit 200A has a connection line 230, and the conductive connector structure 102 has a conductive pillar 14 and a conductive pillar 15 in different height, wherein the conductive caps 12 are formed on the conductive pillar 14 and the conductive pillar 15 respectively. For example, the conductive pillar 14 overlying the through vias 112, 113 may be direct in contact with the connection line 150, and the conductive pillar 15 overlying the through via 114 may be direct in contact with the at least two edge members 1141b. Further, the conductive caps 12 may be direct in contact with the connection line 230. On the other hand, the underfill 20 in FIG. 2 may also be formed in gaps between the circuit unit 100C and the circuit unit 200A (not shown).

Referring to FIG. 7A to FIG. 7D, a substrate S6 includes a circuit unit 100D, a circuit unit 200B, and a conductive connector structure 103. The circuit unit 100D includes a base layer 120A and a via structure 110D penetrated through the base layer 120A, wherein the base layer 120A includes ceramic, but the disclosure is not limited to, the base layer 120A may use other suitable materials. The circuit unit 200B includes a base layer 220A and a via structure 210 penetrated through the base layer 220, wherein the base layer 220 comprises glass, but the disclosure is not limited to, the base layer 220A may use other suitable materials. The circuit unit 200B is bonded and electrically connected to the circuit unit 100D by the conductive connector structure 103. In unillustrated embodiment, the circuit unit 100D and conductive connector structure 103 may be arranged similar to the substrate S2 in FIG. 3

In the embodiment, the circuit unit 100D has a connection line 150, and the via structure 110D including a through via 112, 115, 116. To be specific, the through via 115 has an optical member 1151 and an annular insulator 1152 surrounding the optical member 1151, wherein the optical member 1151 is transmitted by the optical lens 250. Further, the through via 116 has a central member 1161a including optical material, an annular edge members 1161b, and an annular insulator 1162 located between the central member 1161a and the annular edge member 1161b, wherein the central member 1161a is transmitted by the optical lens 250. Here, the annular edge member 1161b may have ground function. In addition, the insulator 1152, 1162 may reduce stress between in the circuit unit 100D, wherein the insulator 1152, 1162 may use any suitable insulating material. Here, each size of the through vias 112, 115, 116 may be greater than a size of the through via 211. Further, a low stress optical and electrical TGV (Through Glass Via) structure may be provided. Moreover, a refractive index of the annular edge member 1161b is a refractive index of the central member 1161a.

In the embodiment, the conductive connector structure 103 has a conductive pillar and a conductive pillar 17 in different height, wherein the conductive caps 12 are formed on the conductive pillar 16 and the conductive pillar 17 respectively. For example, a set of the conductive pillar 16 and the conductive caps 12 overlying the through vias 112 may be direct in contact with the connection line 150 and the through via 211 respectively, and a set of the conductive pillar 17 and the conductive caps 12 overlying the through via 116 may be direct in contact with the connection line 150 and connection line 230B of the circuit unit 200 respectively. Moreover, the circuit unit 200B has optical vias 240 are located above the optical member 1151 and the central member 1161a. On the other hand, the underfill 20 in FIG. 2 may also be formed in gaps between the circuit unit 100D and the circuit unit 200B (not shown). In addition, the conductive pillar 17 may be used to control height between the circuit unit 100D and the circuit unit 200B, by doing so, an optical quality may be better.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A substrate, comprising:
a first circuit unit, comprising a first base layer and a first via structure penetrated through the first base layer, wherein the first via structure has a plurality of first through vias, one of the plurality of first through vias has an optical member and an annular insulator located beside the optical member;
a second circuit unit, comprising a second base layer and a second via structure penetrated through the second base layer; and
a conductive connector structure, wherein the second circuit unit is bonded and electrically connected to the first circuit unit by the conductive connector structure.

2. The substrate according to claim 1, wherein:
the first circuit unit has a first top surface beside the conductive connector structure;
the second circuit unit has a second top surface away from the conductive connector structure; and
a roughness of the first top surface is rougher than a roughness of the second top surface.

3. The substrate according to claim 1, wherein a thickness of the first circuit unit is greater than a thickness of the second circuit unit.

4. The substrate according to claim 1, wherein top surfaces of the plurality of first through vias are not located at a same level.

5. The substrate according to claim 4, wherein a shorter one in the plurality of first through vias is located underlying a taller one in the plurality of conductive pillars.

6. The substrate according to claim 5, wherein the conductive connector structure has a plurality of conductive pillars, and top surfaces of the plurality of conductive pillars are located at a same level.

7. The substrate according to claim 1, further comprising a first redistribution structure disposed on and electrically connected to the second circuit unit.

8. The substrate according to claim 1, further comprising an underfill surrounding the conductive connector structure.

9. The substrate according to claim 1, wherein the first circuit unit further comprises a second redistribution structure and a third redistribution structure, the second redistribution structure and the third redistribution structure are disposed on the opposite surfaces of the first base layer and the first via structure respectively, and a thickness of the second redistribution structure away from the conductive connector structure is greater than a thickness of the third redistribution structure near the conductive connector structure.

10. The substrate according to claim 1, further comprising: an annular edge member surrounding the annular insulator, wherein the annular edge member has ground function.

11. A substrate, comprising:
a first circuit unit, comprising a first base layer and a first via structure penetrated through the first base layer, wherein the first base layer comprises ceramic;
a second circuit unit, comprising a second base layer and a second via structure penetrated through the second base layer, wherein the second base layer comprises glass; and
a conductive connector structure, wherein the second circuit unit is bonded and electrically connected to the first circuit unit by the conductive connector structure.

12. The substrate according to claim 11, wherein the first via structure has a plurality of first through vias, the first circuit unit has a connection line, one of the plurality of first through vias has an annular conductive member and an insulator located in the annular conductive member, and the annular conductive members is electrically connected to the connection line.

13. The substrate according to claim 11, wherein the first via structure has a plurality of first through vias, one of the plurality of first through vias has a conductive member and an annular insulator surrounding the conductive member.

14. The substrate according to claim 11, wherein the first via structure has a plurality of first through vias, one of the plurality of first through vias has a central member, an annular edge member, and an annular insulator located between the central member and the annular edge member.

15. The substrate according to claim 14, wherein a material of the central member comprises a conductive material.

16. The substrate according to claim 14, wherein the annular edge member has ground function.

17. A manufacturing method of a substrate, comprising:
providing a first circuit unit comprising a first base layer and a first via structure penetrated through the first base layer, wherein the first base layer comprises ceramic;
forming a conductive connector structure on the first circuit unit;
providing a second circuit unit comprising a second base layer and a second via structure penetrated through the second base layer, wherein the second base layer comprises glass; and
bonding and electrically connecting the second circuit unit to the first circuit unit by the conductive connector structure.

18. The manufacturing method of substrate according to claim 17, further comprising: forming a first redistribution structure on and electrically connected to the second circuit unit.

19. The manufacturing method of substrate according to claim 17, further comprising: forming an underfill in gaps between the first circuit unit and the second circuit unit.

20. The manufacturing method of substrate according to claim 19, wherein the first circuit unit further comprises a recess, and the underfill is filled up the recess.
